(19) United States
(12) Patent Application Publication
(10) Pub. No.: US 2022/0285639 A1
(43) Pub. Date: Sep. 8, 2022

(54) SOLAR CELL

(71) Applicant: Panasonic Intellectual Property Management Co., Ltd., Osaka (JP)

(72) Inventors: TAISUKE MATSUI, Osaka (JP); KENJI KAWANO, Osaka (JP); AKIO MATSUSHITA, Osaka (JP); MAKI HIRAOKA, Nara (JP)

(21) Appl. No.: 17/664,427

(22) Filed: May 23, 2022

Related U.S. Application Data
(63) Continuation of application No. PCT/JP2020/043100, filed on Nov. 19, 2020.

(30) Foreign Application Priority Data
Dec. 24, 2019 (JP) 2019-233473

(51) Int. Cl. H01L 51/42; H01L 51/00

(52) U.S. Cl. CPC H01L 51/4226; H01L 51/4213; H01L 51/4233; H01L 51/422; H01L 51/006; H01L 2251/303

(57) ABSTRACT

A solar cell 100 includes a substrate 1, a first electrode 6, a carrier transport layer, such as a hole transport layer 5, a first photoelectric conversion layer 3, and a coating layer 4. The first photoelectric conversion layer is disposed between the first electrode 6 and the substrate 1. The substrate 1 has a first main surface and a second main surface, and the second main surface has an uneven structure. The first photoelectric conversion layer 3 has a first main surface and a second main surface, and the first main surface and the second main surface each have an uneven structure. The coating layer 4 has a first main surface and a second main surface, and the first main surface and the second main surface each have an uneven structure.

### BACKGROUND

### 1. Technical Field

The present disclosure relates to solar cells.

### 2. Description of the Related Art

Organic photovoltaics or perovskite solar cells have recently been studied and developed as new solar cells replacing existing silicon solar cells.

Perovskite solar cells use, as photoelectric conversion materials, perovskite compounds represented by chemical formula ABX₃ (wherein A is a monovalent cation, B is a divalent cation, and X is a halogen anion).

Non-Patent Literature 1 (Julian Burschka et al., “Sequential deposition as a route to high-performance perovskite-sensitized solar cells”, Nature, vol. 499, pp. 316-319, 18 Jul. 2013 [DOI:10.1038/nature12340]) discloses a perovskite solar cell that includes, as a photoelectric conversion material for perovskite solar cells, a perovskite compound represented by chemical formula CH₃NH₃PbI₃ (hereinafter referred to as “MAPbI₃”). In the perovskite solar cell disclosed in Non-Patent Literature 1, the perovskite compound represented by MAPbI₃, TiO₂, and Spiro-OMeTAD are used as a photoelectric conversion material, an electron transport material, and a hole transport material, respectively.

Non-Patent Literature 2 (Taisuke Matsui et al., “Room-Temperature Formation of Highly Crystalline Multication Perovskites for Efficient, Low-Cost Solar Cells”, Advanced Materials, Volume29, Issue15, Apr. 18, 2017, 1606258 [DOI: 10.1002/adma.201606258]) discloses a perovskite solar cell that includes, as a photoelectric conversion material for perovskite solar cells, a multi-cation perovskite compound containing CH₃NH₃⁺ (hereinafter referred to as “MA”), CH(NH₂)₂⁺ (hereinafter referred to as “FA”), and Cs as monovalent cations. In the perovskite solar cell disclosed in Non-Patent Literature 2, the multi-cation perovskite compound, TiO₂, and Spiro-OMeTAD are used as a photoelectric conversion material, an electron transport material, and a hole transport material, respectively.

Patent Literature 1 (WO 2014/208713) discloses an organic photovoltaic. The organic photovoltaic disclosed in Patent Literature 1 has an uneven fine structure at the interface between a photoelectric conversion layer and an electrode. With this configuration, the organic photovoltaic disclosed in Patent Literature 1 can improve the photoelectric energy conversion efficiency.

### SUMMARY

One non-limiting and exemplary embodiment provides a perovskite solar cell having a high voltage and less variation in voltage and including a photoelectric conversion layer and a carrier transport layer on a surface having an uneven structure.

In one general aspect, the techniques disclosed here feature a solar cell includes a substrate, a first electrode, a carrier transport layer, a first photoelectric conversion layer, and a coating layer. The first photoelectric conversion layer is disposed between the first electrode and the substrate. The substrate has a first main surface and a second main surface, and the second main surface of the substrate has an uneven structure. The first photoelectric conversion layer has a first main surface and a second main surface, and the first main surface and the second main surface of the first photoelectric conversion layer each have an uneven structure. The coating layer has a first main surface and a second main surface, and the first main surface and the second main surface of the coating layer each have an uneven structure. The second main surface of the substrate faces the first main surface of the first photoelectric conversion layer. The second main surface of the first photoelectric conversion layer faces the first main surface of the coating layer. The second main surface of the coating layer is in contact with the carrier transport layer. The first photoelectric conversion layer contains a perovskite compound. The coating layer contains a compound having 6 or more carbon atoms and containing an ammonium cation.

The present disclosure provides a perovskite solar cell having a high voltage and less variation in voltage and including a photoelectric conversion layer and a carrier transport layer on a surface having an uneven structure.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a cross-sectional view of a solar cell according to a first embodiment;

FIG. 1B is an enlarged cross-sectional view of the solar cell according to the first embodiment;

FIG. 2A is a view for describing a protrusion of the uneven structure in the solar cell according to the first embodiment;

FIG. 2B is a view for describing a recess of the uneven structure in the solar cell according to the first embodiment;

FIG. 3 is a view for describing a height h1 of the uneven structure of a first photoelectric conversion layer and a thickness h2 of a hole transport layer;

FIG. 4A is a cross-sectional view of a modification of the solar cell according to the first embodiment;

FIG. 4B is an enlarged cross-sectional view of the modification of the solar cell according to the first embodiment;

FIG. 5A is a cross-sectional view of a solar cell according to a second embodiment;

FIG. 5B is an enlarged cross-sectional view of the solar cell according to the second embodiment;

FIG. 6A is a cross-sectional view of the modification of the solar cell according to the second embodiment; and

FIG. 6B is an enlarged cross-sectional view of the modification of the solar cell according to the second embodiment.

### DETAILED DESCRIPTIONS

### Definition of Terms

The term “perovskite compound” as used herein refers to a perovskite crystal structure represented by chemical formula ABX₃ (wherein A is a monovalent cation, B is a divalent cation, and X is a halogen anion) and a similar crystal structure.

The term “perovskite solar cell” as used herein refers to a solar cell including a perovskite compound as a photoelectric conversion material.

The term “lead perovskite compound” as used herein refers to a lead-containing perovskite compound.

The term “lead perovskite solar cell” as used herein refers to a solar cell including a lead perovskite compound as a photoelectric conversion material.

### Underlying Knowledge Forming Basis of the Present Disclosure

The underlying knowledge forming the basis of the present disclosure will be described below.

Perovskite compounds have characteristic physical properties, such as high optical absorption coefficient and long diffusion length. Due to such physical properties, perovskite solar cells with a thickness of several hundreds of nanometers can generate power at high efficiency. In addition, perovskite solar cells use fewer materials than those in existing silicon solar cells, do not require high temperature during formation, and can be formed by coating. Having such characteristics, perovskite solar cells are light in weight and can be formed on a substrate formed of a flexible material, such as a plastic. Accordingly, perovskite solar cells can be placed on areas with weight limits. For example, perovskite solar cells can be developed into building-integrated solar cells in combination with existing members, such as building materials. To produce such a perovskite solar cell in combination with a building material, a perovskite solar cell needs to be formed on a substrate composed of a member having a relatively large uneven structure on the surface.

To further improve the photoelectric conversion efficiency, a multi junction solar cell including a perovskite solar cell and a silicon solar cell stacked on top of each other, that is, a tandem solar cell, has been studied. The silicon solar cell may have a texture structure with an uneven surface in order to effectively use incident light. When the silicon solar cell has a texture structure, the perovskite solar cell thus needs to be formed on the surface having an uneven structure.

A photoelectric conversion layer (i.e., a perovskite compound-containing layer) in the perovskite solar cell has a small thickness. For this, in the case where the photoelectric conversion layer in the perovskite solar cell is formed on the surface having an uneven structure, the formed photoelectric conversion layer has an uneven structure reflecting the uneven structure of the underlying surface. In the case where the carrier transport layer (i.e., hole transport layer) is formed, by coating, on the photoelectric conversion layer having such an uneven structure, the carrier transport layer conforms to the shape of the underlying uneven structure and cannot fully cover the unevenness. As a result, the carrier transport layer is thickly formed on the recesses of the photoelectric conversion layer, and the carrier transport layer is very thinly formed or not formed on the protrusions of the photoelectric conversion layer. If the carrier transport layer is unevenly formed on the photoelectric conversion layer in this manner, the solar cell has variations in voltage and has a low voltage.

In light of these circumstances, the inventors of the present disclosure have found a perovskite solar cell having a high voltage and less variation in voltage and including a photoelectric conversion layer and a carrier transport layer on a surface having an uneven structure.

### Embodiments of Present Disclosure

Embodiments of the present disclosure will be described below in detail with reference to the drawings.

### First Embodiment

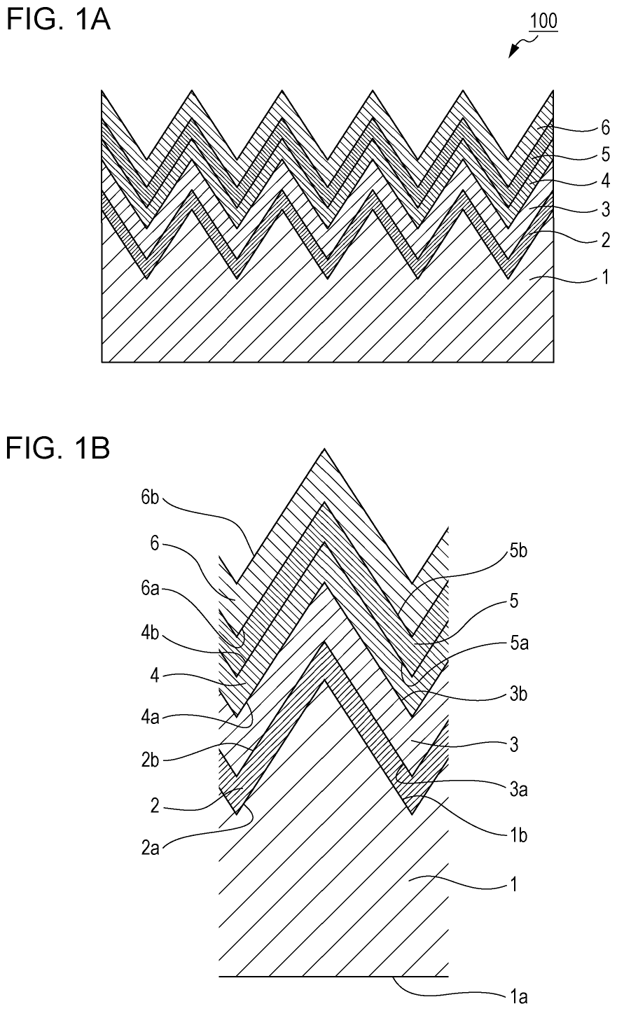

FIG. 1A is a cross-sectional view of a solar cell 100 according to a first embodiment. FIG. 1B is an enlarged cross-sectional view of the solar cell 100 according to the first embodiment.

Referring to FIG. 1A, the solar cell 100 according to the first embodiment includes a substrate 1, an electron transport layer 2, a first photoelectric conversion layer 3, a coating layer 4, a hole transport layer 5, and a first electrode 6. The first photoelectric conversion layer 3 is disposed between the substrate 1 and the first electrode 6.

Specifically, the substrate 1, the electron transport layer 2, the first photoelectric conversion layer 3, the coating layer 4, the hole transport layer 5, and the first electrode 6 are disposed in this order. The first photoelectric conversion layer 3 contains a perovskite compound. In the solar cell 100 according to the first embodiment, a carrier transport layer in contact with the coating layer 4 is the hole transport layer. The solar cell 100 may not include the electron transport layer 2. The components of the solar cell 100 will be described below in detail.

Referring to FIG. 1B, the substrate 1 has a first main surface 1a and a second main surface 1b. The electron transport layer 2 has a first main surface 2a and a second main surface 2b. The first photoelectric conversion layer 3 has a first main surface 3a and a second main surface 3b. The coating layer 4 has a first main surface 4a and a second main surface 4b. The hole transport layer 5 has a first main surface 5a and a second main surface 5b. The first electrode 6 has a first main surface 6a and a second main surface 6b. In FIG. 1A and FIG. 1B, the first main surface of each component corresponds to a lower surface, and the second main surface corresponds to an upper surface.

Referring to FIG. 1B, the second main surface 1b of the substrate 1 has an uneven structure. The first main surface 2a and the second main surface 2b of the electron transport layer 2 each have an uneven structure. The first main surface 3a and the second main surface 3b of the first photoelectric conversion layer 3 each have an uneven structure. The first main surface 4a and the second main surface 4b of the coating layer 4 each have an uneven structure. The first main surface 5a and the second main surface 5b of the hole transport layer 5 each have an uneven structure. The first main surface 6a and the second main surface 6b of the first electrode 6 each have an uneven structure.

The second main surface 1b of the substrate 1 is disposed in contact with the first main surface 2a of the electron transport layer 2. The second main surface 2b of the electron transport layer 2 is disposed in contact with the first main surface 3a of the first photoelectric conversion layer 3. When the solar cell 100 has no electron transport layer 2, the second main surface 1b of the substrate 1 may be in contact with the first main surface 3a of the first photoelectric conversion layer 3. The second main surface 3b of the first photoelectric conversion layer 3 is disposed in contact with the first main surface 4a of the coating layer 4. The second main surface 4b of the coating layer 4 is disposed in contact with the first main surface 5a of the hole transport layer 5. The second main surface 5b of the hole transport layer 5 is disposed in contact with the first main surface 6a of the first electrode 6. A layer having another function may be disposed in at least one of a space between the second main surface 1b of the substrate 1 and the first main surface 2a of the electron transport layer 2, a space between the second main surface 2b of the electron transport layer 2 and the first main surface 3a of the first photoelectric conversion layer 3, a space between the second main surface 3b of the first photoelectric conversion layer 3 and the first main surface 4a of the coating layer 4, or a space between the second main surface 5b of the hole transport layer 5 and the first main surface 6a of the first electrode 6. In other words, the second main surface 1b of the substrate 1 and the first main surface 2a of the electron transport layer 2 face each other and are not necessarily in contact with each other. The second main surface 2b of the electron transport layer 2 and the first main surface 3a of the first photoelectric conversion layer 3 face each other and are not necessarily in contact with each other. When the solar cell 100 includes no electron transport layer 2, the second main surface 1b of the substrate 1 and the first main surface 3a of the first photoelectric conversion layer 3 face each other and are not necessarily in contact with each other. The second main surface 3b of the first photoelectric conversion layer 3 and the first main surface 4a of the coating layer 4 face each other and are not necessarily in contact with each other. In addition, the second main surface 5b of the hole transport layer 5 and the first main surface 6a of the first electrode 6 face each other and are not necessarily in contact with each other.

An example of the “layer having another function” is a porous layer or a second coating layer.

In FIGS. 1A and 1B, the first main surface 5a and the second main surface 5b of the hole transport layer 5 and the first main surface 6a and the second main surface 6b of the first electrode 6 each have an uneven structure. However, the second main surface 5b of the hole transport layer 5 and the first main surface 6a of the first electrode 6 may be flat. Being flat means that the average difference in height of the surface unevenness observed in the cross-sectional image taken with a scanning transmission electron microscope is smaller than or equal to 0.1 μm.

The “uneven structure” as used herein refers to surface unevenness that is observed in the cross-sectional STEM image and in which an average difference in height between protrusions and recesses exceeds 0.1 μm. The average difference in height between protrusions and recesses is determined as described below. First, an arbitrary region with a length of 20 μm is selected from the cross-sectional STEM image. Next, differences in height between protrusions and recesses adjacent to each other are all measured for the surface unevenness of the region. The average difference in height is calculated from the measured values. The average difference in height between protrusions and recesses is determined accordingly.

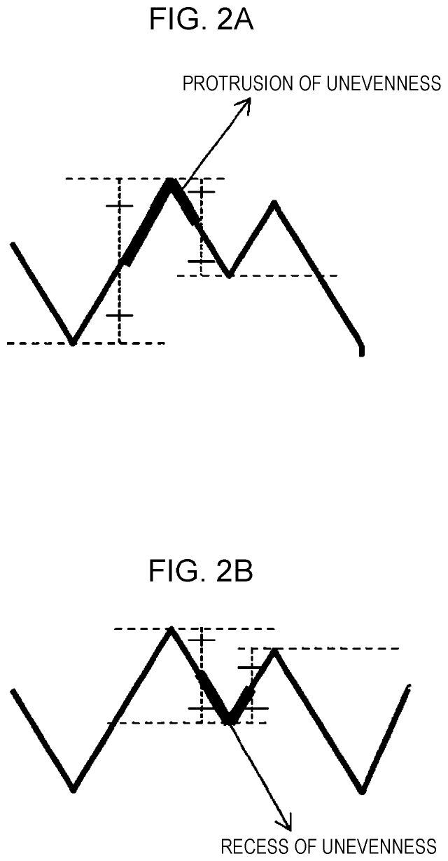

Next, the “protrusions” and the “recesses” of the uneven structure in this description will be described. FIG. 2A is a view for describing a protrusion of the uneven structure in the solar cell 100 according to the first embodiment. FIG. 2B is a view for describing a recess of the uneven structure in the solar cell 100 according to the first embodiment. The protrusion refers to the top of a protrusion shape of the uneven structure and the surrounding area of the top as illustrated in FIG. 2A. The surrounding area of the top is, for example, a region at and above the midpoints between the top and the bottoms of the adjacent recess shapes. The recess refers to the bottom of a recess shape of the uneven structure and the surrounding area of the bottom as illustrated in FIG. 2B. The surrounding area of the bottom of the recess shape is, for example, a region at and below the midpoints between the bottom of the recess shape and the tops of the adjacent protrusion shapes.

In FIG. 1A to FIG. 1B, the first main surface 1a of the substrate 1 is flat but may have an uneven structure. In FIG. 1A, the first photoelectric conversion layer 3 covers the entire surface of the second main surface 2b of the electron transport layer 2, but the electron transport layer 2 may have regions not covered by the first photoelectric conversion layer 3.

The first main surface and the second main surface of each layer may have the same surface roughness or may have different surface roughness.

The coating layer 4 contains a compound having 6 or more carbon atoms and containing an ammonium cation. The coating layer 4 is disposed between the first photoelectric conversion layer 3 and the hole transport layer 5 and in contact with the hole transport layer 5. This configuration reduces the unevenness in the thickness of the hole transport layer 5. A more detailed description is provided. In general, the hole transport layer 5 is formed by coating. For this, in the case where the second main surface 3b of the first photoelectric conversion layer 3 has an uneven structure, the hole transport layer 5 conforms to the shape of the uneven structure of the underlying second main surface 3b and cannot uniformly cover the unevenness. However, when the coating layer 4 is disposed, the coating layer 4 functions as an anchor layer for improving the wettability of a solution used to form the hole transport layer 5. Therefore, the hole transport layer 5 is uniformly formed in contact with the coating layer 4 even above the second main surface 3b of the first photoelectric conversion layer 3 having an uneven structure. This configuration allows the solar cell 100 to have a high voltage and less variation in voltage.

Each layer will be described below in detail.

### Substrate 1

The substrate 1 is, for example, an electrode having electrical conductivity. When the substrate 1 is an electrode, the electrode may or may not transmit light. At least one selected from the group consisting of the substrate 1 and the first electrode 6 transmits light. The substrate 1 holds the electron transport layer 2, the first photoelectric conversion layer 3, the coating layer 4, the hole transport layer 5, and the first electrode 6. When the substrate 1 functions as an electrode, the substrate 1 may include an electrically conductive layer on a base formed of a non-electrically conductive material. In this case, the base formed of a non-electrically conductive material may be transparent.

The light transmitting electrode may transmit light in the visible to near-infrared regions. The light transmitting electrode may be formed of a transparent and electrically conductive material.

Examples of such a material include:
(i) titanium oxide doped with at least one selected from the group consisting of lithium, magnesium, niobium, and fluorine;
(ii) gallium oxide doped with at least one selected from the group consisting of tin and silicon;
(iii) gallium nitride doped with at least one selected from the group consisting of silicon and oxygen;
(iv) indium-tin composite oxide;
(v) tin oxide doped with at least one selected from the group consisting of antimony and fluorine;
(vi) zinc oxide doped with at least one of boron, aluminum, gallium, or indium; and
(vii) composites thereof.

The light transmitting electrode may be formed of a non-transparent material so as to have a pattern through which light passes. Examples of the pattern through which light passes include linear patterns, wavy patterns, lattice patterns, and punched metal patterns having many fine through-holes arranged regularly or irregularly. When the light transmitting electrode has such a pattern, light can pass through areas with no electrode material. Examples of the non-transparent material include platinum, gold, silver, copper, aluminum, rhodium, indium, titanium, iron, nickel, tin, zinc, and alloys containing any one of these metals. The non-transparent material may be an electrically conductive carbon material.

When the solar cell 100 includes the electron transport layer 2 between the first photoelectric conversion layer 3 and the substrate 1, the substrate 1 does not need to have an ability to block holes from the first photoelectric conversion layer 3. Therefore, the material of the substrate 1 may be a material that can be in ohmic contact with the first photoelectric conversion layer 3.

### Electron Transport Layer 2

As described above, the electron transport layer 2 has the first main surface 2a and the second main surface 2b each having an uneven structure. When the electron transport layer 2 is formed on the second main surface 1b of the substrate 1, the uneven structure of the first main surface 2a and the uneven structure of the second main surface 2b may be formed so as to conform to the shape of the uneven structure of the second main surface 1b of the substrate 1. The first main surface 2a of the electron transport layer 2 faces the second main surface 1b of the substrate 1. The first main surface 1a of the electron transport layer 2 may be in contact with the second main surface 1b of the substrate 1.

The electron transport layer 2 transports electrons. The electron transport layer 2 contains a semiconductor. The electron transport layer 2 is preferably formed of a semiconductor having a band gap greater than or equal to 3.0 eV. The electron transport layer 2 formed of a semiconductor having a band gap greater than or equal to 3.0 eV allows visible light and infrared light to be transmitted to the first photoelectric conversion layer 3. Examples of the semiconductor include organic or inorganic n-type semiconductors.

Examples of the organic n-type semiconductors include imide compounds, quinone compounds, fullerene, and fullerene derivatives. Examples of the inorganic n-type semiconductors include metal oxides, metal nitrides, and perovskite oxides. Examples of the metal oxides include oxides of Cd, Zn, In, Pb, Mo, W, Sb, Bi, Cu, Hg, Ti, Ag, Mn, Fe, V, Sn, Zr, Sr, Ga, Si, or Cr. TiO₂ is preferred. Examples of the metal nitrides include GaN. Examples of the perovskite oxides include SrTiO₃, CaTiO₃, and ZnTiO₃.

The electron transport layer 2 may be formed of a substance having a band gap greater than 6.0 eV. Examples of the substance having a band gap greater than 6.0 eV include:
(i) halides of alkali metals or alkaline earth metals, such as lithium fluoride or barium fluoride; and
(ii) oxides of alkaline earth metals, such as magnesium oxide.

In this case, the thickness of the electron transport layer 2 may be, for example, less than or equal to 10 nm in order to ensure the electron transport ability of the electron transport layer 2.

The electron transport layer 2 may include two or more layers made of different materials.

When the substrate 1 in contact with the electron transport layer 2 has an ability to block holes from the first photoelectric conversion layer 3, an electron transport material is not necessarily present. The ability to block holes means that there is no ohmic contact between the first photoelectric conversion layer 3 and the substrate 1. Examples of materials having such a function include aluminum.

### First Photoelectric Conversion Layer 3

The first photoelectric conversion layer 3 contains a perovskite compound. In other words, the first photoelectric conversion layer 3 contains, as a photoelectric conversion material, a perovskite compound composed of a monovalent cation, a divalent cation, and a halogen anion. The photoelectric conversion material is a light absorbing material.

In this embodiment, the perovskite compound may be represented by chemical formula ABX₃ (wherein A is a monovalent cation, B is a divalent cation, and X is a halogen anion).

In accordance with the expressions commonly used for perovskite compounds, A, B, and X are also respectively referred to as the A site, the B site, and the X site in this specification.

In the first embodiment, the perovskite compound may have a perovskite crystal structure represented by chemical formula ABX₃. For example, a monovalent cation is located at the A site, a divalent cation is located at the B site, and a halogen anion is located at the X site.

### A Site

The monovalent cation located at the A site is not limited. Examples of the monovalent cation include organic cations and alkali metal cations. Examples of the organic cations include a methylammonium cation (i.e., CH₃NH₃⁺), a formamidinium cation (i.e., NH₂CHNH₂⁺), a phenylethylammonium cation (i.e., C₆H₅C₂H₄NH₃⁺), and a guanidinium cation (i.e., CH₆N₃⁺). Examples of the alkali metal cations include a cesium cation (i.e., Cs⁺).

To improve the photoelectric conversion efficiency, the A site may include, for example, at least one selected from the group consisting of Cs⁺, a formamidinium cation, and a methylammonium cation.

The cation at the A site may include two or more of the organic cations described above. The cation at the A site may include at least one of the organic cations described above and at least one of metal cations.

### B Site

The divalent cation located at the B site is not limited. Examples of the divalent cation include divalent cations of the group 13 elements to the group 15 elements. For example, the B site includes a Pb cation, that is, Pb²⁺.

### X Site

The halogen anion located at the X site is not limited.

The X site may mainly include an iodide ion. The “halogen anion mainly includes an iodide ion” means that the ratio of the number of moles of iodide ions to the total number of moles of halogen anions is the highest. The X site may be substantially composed only of an iodide ion. The sentence “the X site is substantially composed only of an iodide ion” means that the ratio of the number of moles of iodide ions to the total number of moles of anions is greater than or equal to 90%, preferably greater than or equal to 95%.

The element, or ion, located at each of the A, B, and X sites may include two or more ions or may include one ion.

The first photoelectric conversion layer 3 may contain a material other than the photoelectric conversion material. For example, the first photoelectric conversion layer 3 may further contain a quencher substance for reducing the defect density of the perovskite compound. The quencher substance is a fluorine compound, such as tin fluoride. The molar ratio of the quencher substance to the photoelectric conversion material may be greater than or equal to 5% and less than or equal to 20%.

The first photoelectric conversion layer 3 may mainly contain a perovskite compound composed of a monovalent cation, a divalent cation, and a halogen anion.

The sentence “the first photoelectric conversion layer 3 mainly contains a perovskite compound composed of a monovalent cation, a divalent cation, and a halogen anion” means that the first photoelectric conversion layer 3 contains 70 mass % or more (preferably 80 mass % or more) of a perovskite compound composed of a monovalent cation, a divalent cation, and a halogen anion.

The first photoelectric conversion layer 3 may contain an impurity. The first photoelectric conversion layer 3 may further contain a compound other than the perovskite compound described above.

The first photoelectric conversion layer 3 may have a thickness greater than or equal to 100 nm and less than or equal to 10 μm, preferably a thickness greater than or equal to 100 nm and less than or equal to 1000 nm. The thickness of the first photoelectric conversion layer 3 depends on the amount of its light absorption.

The perovskite layer in the first photoelectric conversion layer 3 may be formed by using a solution coating method, a co-deposition method, or other methods.

The first photoelectric conversion layer 3 has the first main surface 3a and the second main surface 3b each having an uneven structure. When the first photoelectric conversion layer 3 is formed on the second main surface 2b of the electron transport layer 2 or the second main surface 1b of the substrate 1, the uneven structure of the first main surface 3a and the uneven structure of the second main surface 3b may be formed so as to conform to the shape of the uneven structure of the second main surface 2b of the electron transport layer 2 or the second main surface 1b of the substrate 1.

The first photoelectric conversion layer 3 is in contact with the electron transport layer 2 described above and may be partially mixed with the electron transport layer 2 or may have, in the layer, a large area interface with the electron transport layer 2.

### Coating Layer 4

As described above, the coating layer 4 improves the coatability of the hole transport layer 5 when it is formed on the first photoelectric conversion layer 3. The holes generated in the first photoelectric conversion layer 3 move to the hole transport layer 5 through the coating layer 4. However, the coating layer 4 preferably does not inhibit the hole transport ability. Thus, the coating layer 4 is preferably as thin as possible, and preferably has a thickness less than or equal to 100 nm, more preferably has a thickness less than or equal to 10 nm.

As described above, the coating layer 4 contains a compound having 6 or more carbon atoms and containing an ammonium cation. This compound may be an alkylammonium having 6 or more and 20 or less carbon atoms. When the number of carbon atoms is less than or equal to 20, the coating layer 4 can prevent inhibition of charge injection.

As the number of carbon atoms in the compound constituting the coating layer 4 increases and the distance between the first photoelectric conversion layer 3 and the hole transport layer 5 increases, the inhibition of charge injection occurs. From this viewpoint, the number of carbon atoms in the compound constituting the coating layer 4 may be less than or equal to 20. Preferably, the number of carbon atoms in the compound constituting the coating layer 4 may be less than or equal to 10.

The compound may contain a compound represented by chemical formula R—X. In the chemical formula, R is phenyl ethyl ammonium, hexa-ammonium, or octa-ammonium, and X is a halogen.

### Hole Transport Layer 5

The hole transport layer 5 contains a hole transport material. The hole transport material is a material that transports holes. Examples of the hole transport material include organic substances or inorganic semiconductors.

Examples of representative organic substances used as the hole transport material include 2,2′,7,7′-tetrakis-(N,N-di-p-methoxyphenylamine)9,9′-spirobifluorene (hereinafter referred to as “spiro-OMeTAD”), poly[bis(4-phenyl)(2,4,6-trimethylphenyl)amine] (hereinafter referred to as “PTAA”), poly(3-hexylthiophene-2,5-diyl) (hereinafter referred to as “P3HT”), poly(3,4-ethylenedioxythiophene) polystyrene sulfonate (hereinafter referred to as “PEDOT:PSS”), and copper phthalocyanine (hereinafter referred to as “CuPc”).

The inorganic semiconductors are p-type semiconductors. Examples of the inorganic semiconductors include Cu₂O, CuGaO₂, CuSCN, CuI, NiOₓ, MoOₓ, V₂O₅, and carbon materials, such as graphene oxide.

The hole transport layer 5 may include two or more layers made of different materials.

The thickness of the hole transport layer 5 is preferably greater than or equal to 1 nm and less than or equal to 1000 nm, more preferably greater than or equal to 10 nm and less than or equal to 500 nm, still more preferably greater than or equal to 10 nm and less than or equal to 50 nm. When the hole transport layer 5 has a thickness greater than or equal to 1 nm and less than or equal to 1000 nm, the hole transport layer 5 can exhibit a sufficient hole transport ability. When the hole transport layer 5 has a thickness greater than or equal to 1 nm and less than or equal to 1000 nm, the hole transport layer 5 has low resistance and thus allows conversion of light into electricity at high efficiency.

The hole transport layer 5 on the recesses of the second main surface 3b of the first photoelectric conversion layer 3 may have a larger thickness than the hole transport layer 5 on the protrusions of the second main surface 3b of the first photoelectric conversion layer 3.

The hole transport layer 5 may contain an additive and a solvent. The additive and the solvent have, for example, an effect of increasing the hole conductivity of the hole transport layer 5.

Examples of the additive include ammonium salts and alkali metal salts. Examples of the ammonium salts include tetrabutylammonium perchlorate, tetraethylammonium hexafluorophosphate, imidazolium salts, and pyridinium salts. Examples of the alkali metal salts include lithium bis(pentafluoroethanesulfonyl)imide, lithium bis(trifluoromethanesulfonyl)imide (hereafter referred to as “LiTFSI”), LiPF₆, LiBF₄, lithium perchlorate, and potassium tetrafluoroborte.

The solvent contained in the hole transport layer 5 may have high ion conductivity. The solvent may be an aqueous solvent or an organic solvent. To stabilize solutes, the solvent is preferably an organic solvent. Examples of the organic solvent include heterocyclic compounds, such as tert-butylpyridine (hereinafter referred to as “t-BP”), pyridine, and n-methylpyrrolidone.

The solvent contained in the hole transport layer 5 may be an ionic liquid. The ionic liquid may be used alone or as a mixture with another solvent. The ionic liquid is preferred because of its low volatility and high flame retardancy.

Examples of the ionic liquid include imidazolium compounds, such as 1-ethyl-3-methylimidazolium tetracyanoborate, pyridine compounds, alicyclic amine compounds, aliphatic amine compounds, and azonium amine compounds.

The hole transport layer 5 can be formed by various known coating methods or printing methods. Examples of coating methods include a doctor blade method, a bar coating method, a spraying method, a dip coating method, and a spin coating method. Examples of printing methods include a screen printing method.

### First Electrode 6

The first electrode 6 may or may not transmit light. At least one selected from the group consisting of the substrate 1 and the first electrode 6 transmits light.

When the first electrode 6 transmits light, the first electrode 6 may transmit light in the visible to near-infrared regions. The light transmitting electrode may be formed of a transparent and electrically conductive material.

Examples of such a material include:
(i) titanium oxide doped with at least one selected from the group consisting of lithium, magnesium, niobium, and fluorine;
(ii) gallium oxide doped with at least one selected from the group consisting of tin and silicon;
(iii) gallium nitride doped with at least one selected from the group consisting of silicon and oxygen;
(iv) indium-tin composite oxide;
(v) tin oxide doped with at least one selected from the group consisting of antimony and fluorine;
(vi) zinc oxide doped with at least one of boron, aluminum, gallium, or indium; and
(vii) composites thereof.

The light transmitting electrode may be formed of a non-transparent material so as to have a pattern through which light passes. Examples of the pattern through which light passes include linear patterns, wavy patterns, lattice patterns, and punched metal patterns having many fine through-holes arranged regularly or irregularly. When the light transmitting electrode has such a pattern, light can pass through areas with no electrode material. Examples of the non-transparent material include platinum, gold, silver, copper, aluminum, rhodium, indium, titanium, iron, nickel, tin, zinc, and alloys containing any one of these metals. The non-transparent material may be an electrically conductive carbon material.

The solar cell 100 has the hole transport layer 5 between the first photoelectric conversion layer 3 and the first electrode 6. Therefore, the first electrode 6 does not need to have an ability to block electros from the first photoelectric conversion layer 3. In this case, the first electrode 6 may be in ohmic contact with the first photoelectric conversion layer 3.

The first electrode 6 may have a light transmittance greater than or equal to 50%, or greater than or equal to 80%. The wavelength of light transmitted through the first electrode 6 depends on the absorption wavelength of the first photoelectric conversion layer 3. The first electrode 6 has a thickness in the range of, for example, 1 nm or greater and 1000 nm or less.

### Layer Having Another Function

An example of the “layer having another function” is a porous layer. The porous layer is located, for example, between the electron transport layer 2 and the first photoelectric conversion layer 3. The porous layer includes a porous material. The porous material includes pores. The pores in the porous layer located between the electron transport layer 2 and the first photoelectric conversion layer 3 may be connected to one another from areas in contact with the electron transport layer 2 to areas in contact with the first photoelectric conversion layer 3. The pores are typically filled with the material of the first photoelectric conversion layer 3. The electrons may directly move from the first photoelectric conversion layer 3 to the electron transport layer 2.

The porous layer may serve as a base for forming the first photoelectric conversion layer 3 on the substrate 1 and the electron transport layer 2. The porous layer does not inhibit the light absorption of the first photoelectric conversion layer 3 and the movement of electrons from the first photoelectric conversion layer 3 to the electron transport layer 2.

The porous material that may constitute the porous layer is composed of, for example, insulator or semiconductor particles connected to one another. Examples of the insulator particles include aluminum oxide particles and silicon oxide particles. Examples of the semiconductor particles include inorganic semiconductor particles. Examples of the inorganic semiconductor include oxides of metal elements, perovskite oxides of metal elements, sulfides of metal elements, and metal chalcogenides. Examples of the oxides of metal elements include oxides of metal elements, such as Cd, Zn, In, Pb, Mo, W, Sb, Bi, Cu, Hg, Ti, Ag, Mn, Fe, V, Sn, Zr, Sr, Ga, Si, and Cr. Specific examples of the oxides of metal elements include TiO₂. Examples of the perovskite oxides of metal elements include SrTiO₃ and CaTiO₃. Examples of the sulfides of metal elements include CdS, ZnS, In₂S₃, PbS, Mo₂S, WS₂, Sb₂S₃, Bi₂S₃, ZnCdS₂, and Cu₂S. Examples of the metal chalcogenides include CdSe, In₂Se₃, WSe₂, HgS, PbSe, and CdTe.

The porous layer may have a thickness greater than or equal to 0.01 μm and less than or equal to 10 μm, or a thickness greater than or equal to 0.1 μm and less than or equal to 1 μm. The porous layer may have large surface roughness. Specifically, the surface-roughness coefficient of the porous layer given by the effective area/projected area may be greater than or equal to 10, or may be greater than or equal to 100. The projected area is the area of the shadow behind an object when the object is exposed to light from the front surface. The effective area is the actual surface area of the object. The effective area can be calculated from the volume of the object determined by the projected area and thickness of the object, and the specific surface area and bulk density of the material of the object.

Another example of the “layer having another function” is a second coating layer. The second coating layer is disposed to prevent short-circuiting caused by direct contact between the first electrode 6 and the electron transport layer 2. The second coating layer has a band gap wide enough to inhibit ohmic contact between the first electrode 6 and the electron transport layer 2. The second coating layer is disposed between the hole transport layer 5 and the first electrode 6 and thus has a hole transport ability. Examples of the material of the second coating layer include compounds containing organic substances, or inorganic semiconductors. Specific examples include oxides containing transition metals, such as molybdenum oxide or tungsten oxide. Depending on the method of forming the first electrode 6 on the second coating layer, the second coating layer may be damaged during formation of the first electrode 6. Therefore, the second coating layer may be made of a material having an effect of preventing damage generated during formation of the first electrode 6.

### Height of Uneven Structure in Second Surface b of First Photoelectric Conversion Layer 3

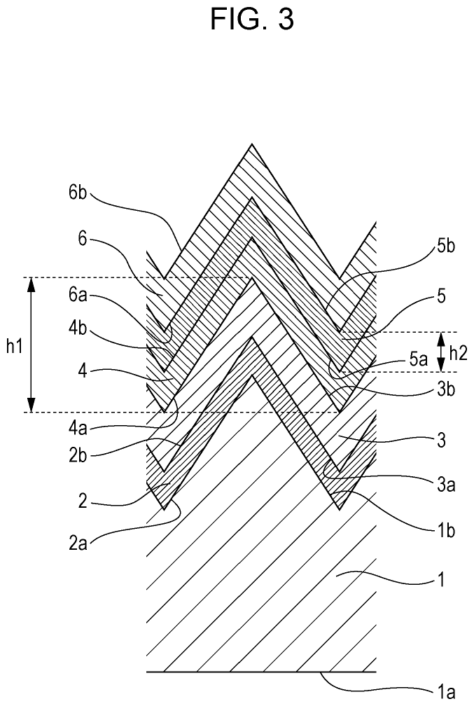

FIG. 3 is a view for describing a height h1 of the uneven structure of the first photoelectric conversion layer 3 and a thickness h2 of the hole transport layer 5. The height of the uneven structure refers to the height from the bottom of a recess to the top of a protrusion. The thickness of the hole transport layer 5 refers to the height from the bottom of a recess in the first main surface 5a of the hole transport layer 5 to the bottom of a recess in the second main surface 5b of the hole transport layer 5. In this case, the value of h1 is preferably greater than or equal to 0.1 μm and less than or equal to 10 μm. The value of h2 is preferably greater than or equal to 1 nm and less than or equal to 1000 nm. For example, the values of h1 and h2 satisfy the formula: h1>h2. In other words, the value of h1 may be larger than the value of h2. In this case, it is possible to suppress a decrease in current caused by light absorption of the hole transport layer 5 and, at the same time, introduce more light into the first photoelectric conversion layer 3 due to the anti-reflection effect of the uneven structure.

### Modification of Solar Cell 100

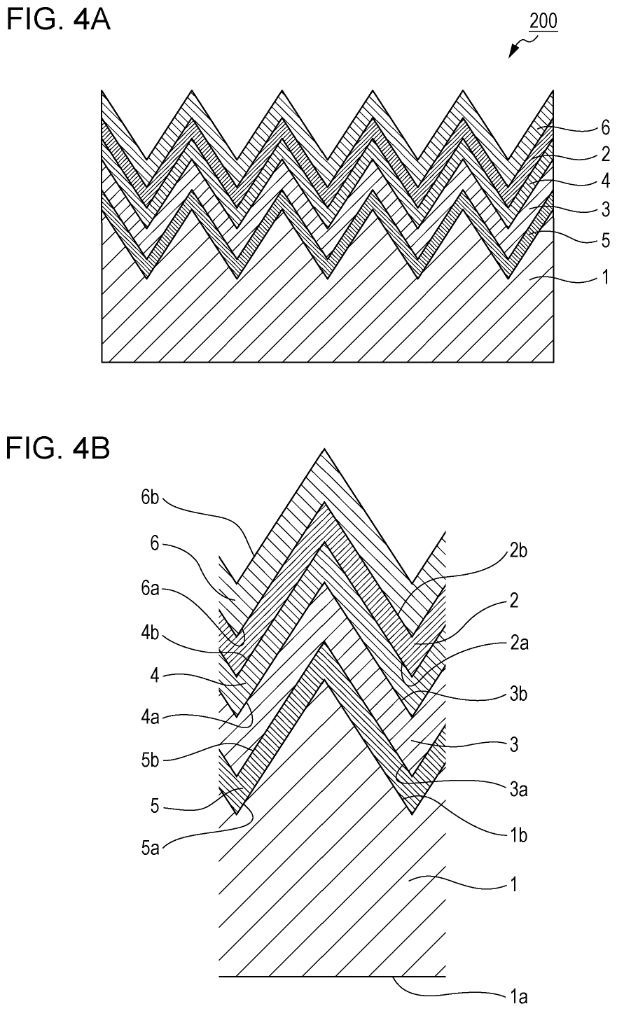

The solar cell 100 in FIGS. 1A and 1B has an exemplary structure in which the carrier transport layer is a hole transport layer, but the carrier transport layer may be an electron transport layer. FIG. 4A is a cross-sectional view of a modification of the solar cell according to the first embodiment. FIG. 4B is an enlarged cross-sectional view of the modification of the solar cell according to the first embodiment. A solar cell 200 in FIGS. 4A and 4B differs from the solar cell 100 in that the hole transport layer 5 and the electron transport layer 2 are disposed at opposite positions. In other words, the electron transport layer 2 is disposed between the first photoelectric conversion layer 3 and the first electrode 6.

### Operation and Effect of Solar Cell 100

Next, the basic operation and effect of the solar cell 100 will be described. In the solar cell 100, at least one selected from the group consisting of the substrate 1 and the first electrode 6 transmits light. Light enters the solar cell 100 from the light transmitting surface. Upon exposure of the solar cell 100 to light, the first photoelectric conversion layer 3 absorbs light to generate excited electrons and holes. The excited electrons move to the electron transport layer 2. The holes generated in the first photoelectric conversion layer 3 move to the hole transport layer 5. The electron transport layer 2 and the hole transport layer 5 are electrically connected to the substrate 1 and the first electrode 6, respectively. The current is drawn from the substrate 1 and the first electrode 6. The substrate 1 and the first electrode 6 function as a negative electrode and a positive electrode, respectively. The hole transport layer 5 and the electron transport layer 2 may be inverted in the light incident direction.

### Example of Method for Producing Solar Cell 100

The solar cell 100 can be produced by, for example, the following method.

First, an electrode having an uneven structure on at least one main surface (i.e., second main surface 1b) is prepared as the substrate 1. Next, the electron transport layer 2 is formed on the second main surface 1b of the substrate 1 by using a coating technique, physical vapor deposition (PVD), chemical vapor deposition (CVD), or other methods. The first photoelectric conversion layer 3 is formed on the electron transport layer 2 by using a coating technique. The first photoelectric conversion layer 3 can also be formed by physical vapor deposition or a combination of physical vapor deposition and a coating technique. The coating layer 4 and the hole transport layer 5 are formed on the first photoelectric conversion layer 3 by using a coating technique, physical vapor deposition, chemical vapor deposition, or other methods. Finally, the first electrode 6 is formed on the hole transport layer 5 by physical vapor deposition. Examples of the coating technique include spin coating, spray coating, die coating, ink-jet coating, gravure coating, flexographic coating, or screen printing. Examples of physical vapor deposition include sputtering. Examples of chemical vapor deposition include deposition using heat, light, plasma, or other energies.

### Second Embodiment

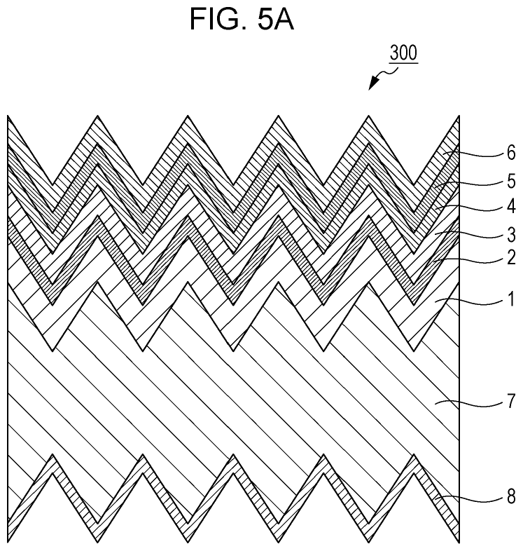

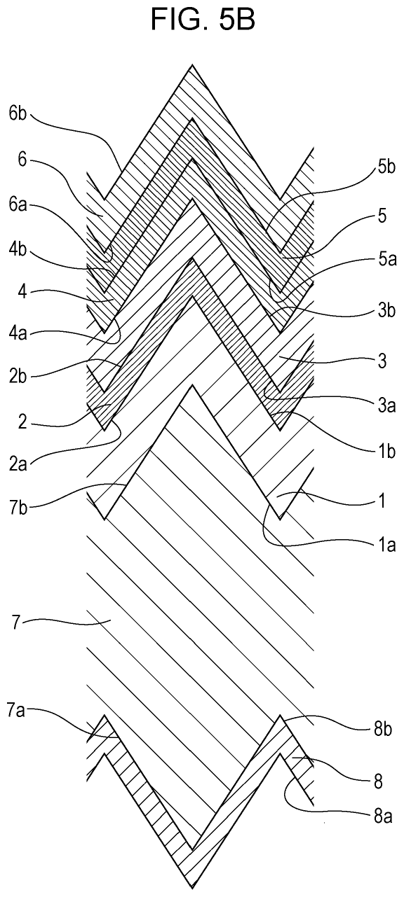

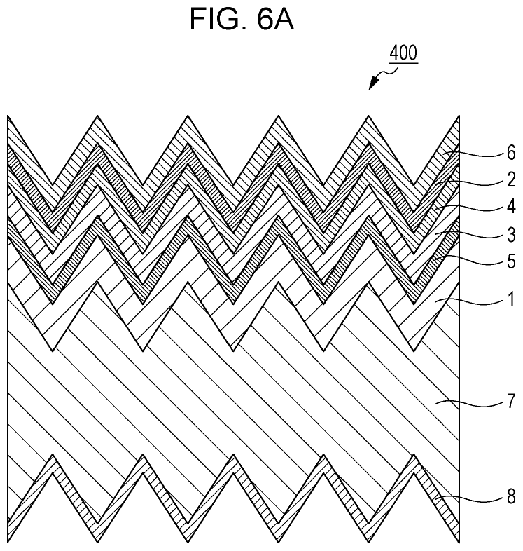

FIG. 5A is a cross-sectional view of a solar cell 300 according to a second embodiment. FIG. 5B is an enlarged cross-sectional view of the solar cell 300 according to the second embodiment.

Referring to FIGS. 5A and 5B, the solar cell 300 according to the second embodiment differs from the solar cell 100 according to the first embodiment in that the solar cell 300 further includes a second photoelectric conversion layer 7 and a second electrode 8. In other words, the solar cell 300 is a multi junction solar cell including two photoelectric conversion layers. The second photoelectric conversion layer 7 faces a first main surface 1a of a substrate 1. In other words, the second photoelectric conversion layer 7 is disposed below the substrate 1. In other words, the second photoelectric conversion layer 7 is disposed between the second electrode 8 and the substrate 1. The second photoelectric conversion layer 7 has a first main surface 7a and a second main surface 7b. The second electrode 8 has a first main surface 8a and a second main surface 8b. In FIG. 5A and FIG. 5B, the first main surface of each component corresponds to a lower surface, and the second main surface corresponds to an upper surface, as in FIG. 1A and FIG. 1B.

The solar cell 300 according to the second embodiment includes the substrate 1, an electron transport layer 2, a first photoelectric conversion layer 3, a coating layer 4, a hole transport layer 5, a first electrode 6, the second photoelectric conversion layer 7, and the second electrode 8. Specifically, the second electrode 8, the second photoelectric conversion layer 7, the substrate 1, the electron transport layer 2, the first photoelectric conversion layer 3, the coating layer 4, the hole transport layer 5, and the first electrode 6 are disposed in this order.

The structure of the solar cell 300 will be described below in detail.

As illustrated in FIG. 5B, the second main surface 2b of the second electrode 8 is in contact with the first main surface 7a of the second photoelectric conversion layer 7. In addition, the second main surface 7b of the second photoelectric conversion layer 7 is in contact with the first main surface 1a of the substrate 1. The first main surface 7a and the second main surface 7b of the second photoelectric conversion layer 7 each have an uneven structure. Each layer above the substrate 1 has the same configuration as the corresponding layer in the solar cell 100 according to the first embodiment. A layer having another function may be disposed in each of spaces between the second main surface 8b of the second electrode 8 and the first main surface 7a of the second photoelectric conversion layer 7 and between the second main surface 7b of the second photoelectric conversion layer 7 and the first main surface 1a of the substrate 1.

The second main surface 7b of the second photoelectric conversion layer 7 faces the first main surface 1a of the substrate 1 and is not necessarily in contact with the first main surface 1a of the substrate 1. Examples of the layer having another function include a porous layer.

The configurations different from those of the solar cell 100 according to the first embodiment will be described below.

### Substrate 1

In a multi junction solar cell like the solar cell 200, the substrate 1 is, for example, a recombination layer. The recombination layer has a function of incorporating carriers generated in the first photoelectric conversion layer 3 and the second photoelectric conversion layer 7 and recombining the carriers. Therefore, the recombination layer preferably has a certain degree of conductivity.

The recombination layer may, for example, transmit light. The light transmitting recombination layer may transmit light in the visible to near-infrared regions. The light transmitting recombination layer may be formed of a transparent and electrically conductive material.

Examples of such a material include:
(i) titanium oxide doped with at least one selected from the group consisting of lithium, magnesium, niobium, and fluorine;
(ii) gallium oxide doped with at least one selected from the group consisting of tin and silicon;
(iii) gallium nitride doped with at least one selected from the group consisting of silicon and oxygen;
(iv) indium-tin composite oxide;
(v) tin oxide doped with at least one selected from the group consisting of antimony and fluorine;
(vi) zinc oxide doped with at least one of boron, aluminum, gallium, or indium; and
(vii) composites thereof.

Examples of the material of the recombination layer include metal oxides, such as ZnO, WO₃, MoO₃, and MoO₂, and electron-accepting organic compounds. Examples of the electron-accepting organic compounds include organic compounds having a CN group as a substituent. Examples of the organic compounds having a CN group as a substituent include triphenylene derivatives, tetracyanoquinodimethane derivatives, and indenofluorene derivatives. Examples of the triphenylene derivatives include hexacyanohexaazatriphenylene. Examples of the tetracyanoquinodimethane derivatives include tetrafluoroquinodimethane and dicyanoquinodimethane. The electron-accepting substance may be a single compound or may be used as a mixture with another organic compound.

### Second Photoelectric Conversion Layer 7

The photoelectric conversion material used for the second photoelectric conversion layer 7 has a smaller band gap than the photoelectric conversion material used for the first photoelectric conversion layer 3. Examples of the photoelectric conversion material used for the second photoelectric conversion layer 7 include silicon, perovskite compounds, chalcopyrite compounds, such as CIGS, and III-V group compounds, such as GaAs. The second photoelectric conversion layer 7 may contain silicon. When the second photoelectric conversion layer 7 contains silicon, the solar cell 200 is a multi junction solar cell including a silicon solar cell and a perovskite solar cell stacked on top of each other. The photoelectric conversion material used for the second photoelectric conversion layer 7 is not limited to those described above as long as it has a smaller band gap than the photoelectric conversion material used for the first photoelectric conversion layer 3. Second Electrode 8

The second electrode 8 may or may not transmit light. At least one selected from the group consisting of the second electrode 8 and the first electrode 6 transmits light.

The light transmitting electrode may transmit light in the visible to near-infrared regions. The light transmitting electrode may be formed of a transparent and electrically conductive material.

Examples of such a material include:
(i) titanium oxide doped with at least one selected from the group consisting of lithium, magnesium, niobium, and fluorine;
(ii) gallium oxide doped with at least one selected from the group consisting of tin and silicon;
(iii) gallium nitride doped with at least one selected from the group consisting of silicon and oxygen;
(iv) indium-tin composite oxide;
(v) tin oxide doped with at least one selected from the group consisting of antimony and fluorine;
(vi) zinc oxide doped with at least one of boron, aluminum, gallium, or indium; and
(vii) composites thereof.

The light transmitting electrode may be formed of a non-transparent material so as to have a pattern through which light passes. Examples of the pattern through which light passes include linear patterns, wavy patterns, lattice patterns, and punched metal patterns having many fine through-holes arranged regularly or irregularly. When the light transmitting electrode has such a pattern, light can pass through areas with no electrode material. Examples of the non-transparent material include platinum, gold, silver, copper, aluminum, rhodium, indium, titanium, iron, nickel, tin, zinc, and alloys containing any one of these metals. The non-transparent material may be an electrically conductive carbon material.

The second electrode 8 may have a light transmittance greater than or equal to 50%, or greater than or equal to 80%. The wavelength of light transmitted through the second electrode 8 depends on the absorption wavelength of the second photoelectric conversion layer 7 and the first photoelectric conversion layer 3. The second electrode 8 has a thickness in the range of, for example, 1 nm or greater and 1000 nm or less.

### Modification of Solar Cell 300

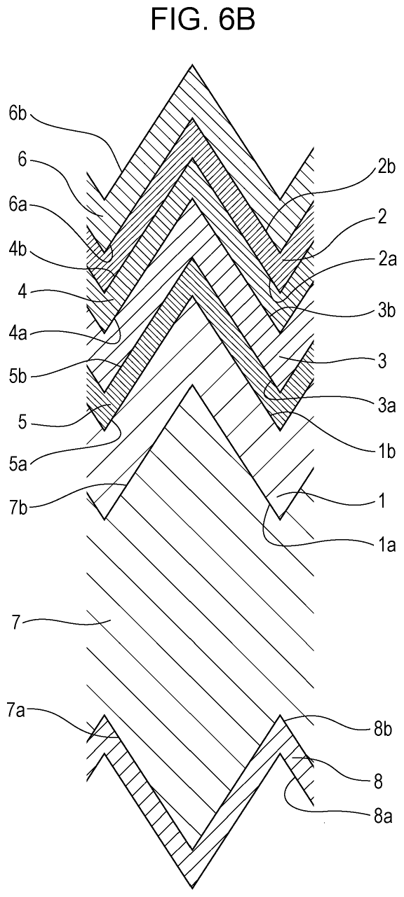

A solar cell 300 in FIGS. 5A and 5B has an exemplary structure in which the carrier transport layer is a hole transport layer, but the carrier transport layer may be an electron transport layer. FIG. 6A is a cross-sectional view of the modification of the solar cell according to the second embodiment. FIG. 6B is an enlarged cross-sectional view of the modification of the solar cell according to the second embodiment. A solar cell 400 in FIGS. 6A and 6B differs from the solar cell 300 in that the hole transport layer 5 and the electron transport layer 2 are disposed at opposite positions. In other words, the electron transport layer 2 is disposed between the first photoelectric conversion layer 3 and the first electrode 6.

### Operation and Effect of Solar Cell 300

Next, the basic operation and effect of the solar cell 300 will be described. In the solar cell 300, at least one selected from the group consisting of the second electrode 8 and the first electrode 6 transmits light. When the first electrode 6 transmits light, for example, light enters the solar cell 300 from the surface of the first electrode 6 in the solar cell 300. Upon exposure of the solar cell 300 to light, the first photoelectric conversion layer 3 absorbs light to generate excited electrons and holes. The excited electrons move to the electron transport layer 2. The holes generated in the first photoelectric conversion layer 3 move to the hole transport layer 5. Light that is not absorbed by the first photoelectric conversion layer 3 passes through the electron transport layer 2 and the substrate 1 and is absorbed by the second photoelectric conversion layer 7. The second photoelectric conversion layer 7 generates excited electrons and holes when it absorbs light. The excited electrons move to the second electrode 8. The holes generated in the second photoelectric conversion layer 7 move to the substrate 1. The electrons that have moved from the first photoelectric conversion layer 3 to the substrate 1 and the holes that have moved from the second photoelectric conversion layer 7 to the substrate 1 are recombined in the substrate 1. The current is drawn from the second electrode 8 and the first electrode 6. The second electrode 8 and the first electrode 6 function as a negative electrode and a positive electrode, respectively.

### Example of Method for Producing Solar Cell 300

The solar cell 300 can be produced by, for example, the following method.

First, the second photoelectric conversion layer 7 composed of an n-type silicon single crystal and having an uneven structure on one main surface (i.e., a main surface corresponding to the second main surface 7b) is prepared. Next, the second electrode 8 is formed on the first main surface 7a of the second photoelectric conversion layer 7 by using a coating technique, physical vapor deposition, chemical vapor deposition, or other methods. The substrate 1 functioning as a recombination layer is formed on the second main surface 7b of the second photoelectric conversion layer 7 by using physical vapor deposition or vacuum heating deposition. The electron transport layer 2 is then formed on the second main surface 1b of the substrate 1. The first photoelectric conversion layer 3 is formed on the electron transport layer 2 by using a coating technique. The first photoelectric conversion layer 3 can also be formed by physical vapor deposition or a combination of physical vapor deposition and a coating technique. The coating layer 4 and the hole transport layer 5 are formed on the first photoelectric conversion layer 3 by using a coating technique, physical vapor deposition, chemical vapor deposition, or other methods. Finally, the first electrode 6 is formed on the hole transport layer 5 by physical vapor deposition. Examples of the coating technique include spin coating, spray coating, die coating, ink-jet coating, gravure coating, flexographic coating, or screen printing. Examples of physical vapor deposition include sputtering. Examples of chemical vapor deposition include deposition using heat, light, plasma, or other energies.

The solar cells 300 and 400 according to the second embodiment include two photoelectric conversion layers. In other words, the solar cells 300 and 400 are double-junction solar cells including two solar cells connected to each other. The number of connected solar cells is not limited to two, and three or more solar cells may be connected to each other.

### Solar Cell According to Another Aspect of Present Disclosure

A solar cell according to the present disclosure may be specified as described below.

The solar cell according to another aspect of the present disclosure includes:
a substrate;
a first photoelectric conversion layer;
a coating layer;
a carrier transport layer; and
a first electrode.

The substrate, the first photoelectric conversion layer, the coating layer, the carrier transport layer, and the first electrode are disposed in this order.

The coating layer is in contact with the carrier transport layer.

A main surface of the substrate has an uneven structure, the main surface facing the first photoelectric conversion layer.

A first main surface and a second main surface of the first photoelectric conversion layer each have an uneven structure, the first main surface facing the substrate, the second main surface facing the coating layer.

A first main surface and a second main surface of the coating layer each have an uneven structure, the first main surface facing the first photoelectric conversion layer, the second main surface facing the carrier transport layer.

The first photoelectric conversion layer contains a perovskite compound.

The coating layer contains a compound having 6 or more carbon atoms and containing an ammonium cation.

The solar cell according to the above aspect is a perovskite solar cell including a photoelectric conversion layer and a carrier transport layer on a surface having an uneven structure and has a high voltage and less variation in voltage.

### EXAMPLES

The present disclosure will be described in more detail with reference to Examples below.

### Example 1

In Example 1, the solar cell 100 illustrated in FIG. 1 is produced as described below. The elements of the solar cell 100 of Example 1 are as described below.

Substrate 1: a silicon substrate having a tin-doped indium oxide layer thereon and having a texture surface of 2.0 μm (i.e., the average difference in height between protrusions and recesses on the texture surface is 2.0 μm.)
Electron transport layer 2: a TiO₂ layer (thickness: 15 nm)
Porous layer: a porous layer containing TiO₂ as a main component
First photoelectric conversion layer 3: a layer mainly containing a perovskite compound CH(NH₂)₂PbI₃
Coating layer 4: a phenethylammonium iodide layer
Hole transport layer 5: a Spiro-OMeTAD-containing layer (containing LiN(SO₂CF₃)₂ and 4-tert-butyl pyridine (hereinafter referred to as “t-BP”) as an additive and a solvent, respectively)
Second coating layer: a molybdenum oxide layer (thickness: 10 nm)
Second electrode 6: a tin-doped indium oxide layer (thickness: 200 nm)

A specific production method is described below.

First, a silicon substrate having a tin-doped indium oxide layer on the surface and having a texture surface of 2.0 μm was prepared as the substrate 1.

Next, a TiO₂ film having a thickness of 15 nm was formed as the electron transport layer 2 on the tin-doped indium oxide layer of the substrate 1 by a sputtering method.

Next, 30NR-D (available from GreatCell Solar Limited) was applied onto the electron transport layer 2 by spin coating and heat-treated at 500° C. for 30 minutes. The porous layer containing TiO₂ as a main component was formed accordingly.

Next, the first photoelectric conversion layer 3 was formed on the porous layer by spin-coating a first material solution. The first material solution was a solution containing 0.92 mol/L of PbI₂ (available from Tokyo Chemical Industry Co., Ltd.), 0.17 mol/L of PbBr₂ (available from Tokyo Chemical Industry Co., Ltd.), 0.83 mol/L of formamidinium iodide (available from GreatCell Solar Limited) (hereinafter referred to as “FAI”), 0.17 mol/L of methylammonium bromide (available from GreatCell Solar Limited) (hereinafter referred to as “MABr”), and 0.05 mol/L of CsI (available from Iwatani Corporation). The solvent of the solution was a mixture of dimethyl sulfoxide (available from Acros Organics) and N,N-dimethylformamide (available from Acros Organics). The mixing ratio of dimethyl sulfoxide and N,N-dimethylformamide (dimethyl sulfoxide:N,N-dimethylformamide) in the first material solution was 1:4 (volume ratio).

Next, the material solution of the coating layer 4 was applied onto the first photoelectric conversion layer 3 by spin coating and then heated at 100° C. for 5 minutes. The coating layer 4 was formed accordingly. The material solution of the coating layer 4 was a solution of 1 mg of phenethylammonium iodide (PEAT) (available from GreatCell Solar Limited) in 1 mL of isopropanol (available from Acros Organics).

Next, the second material solution was applied onto the coating layer 4 by spin coating. The hole transport layer 5 was formed accordingly. The second material solution was a solution of 90 mg of Spiro-OMeTAD (available from Merck), 36 μL of t-BP (available from Aldrich Chemical Co. Inc.), and 20 μL of LiN(SO₂CF₃)₂ (available from Tokyo Chemical Industry Co., Ltd.) acetonitrile solution (concentration: 1.8 mol/L) in 1 mL of chlorobenzene (available from Acros Organics).

Next, molybdenum oxide having a thickness of 10 nm was formed on the hole transport layer 5 by vacuum deposition. The molybdenum oxide layer functioned as the second coating layer.

Finally, a tin-doped indium oxide layer having a thickness of 200 nm was deposited on the second coating layer by a sputtering method. The tin-doped indium oxide layer functioned as the first electrode 6.

The solar cell 100 of Example 1 was produced accordingly. The processes described above other than the process for forming the first electrode 6 were carried out in a dry room in a dry atmosphere having a dew point lower than or equal to −40° C.

### Example 2

A solar cell was produced by the same method as in Example 1 except for the following:
(i) Phenethylammonium bromide (PEABr) (available from GreatCell Solar Limited) was used in the material solution of the coating layer 4 instead of phenethylammonium iodide (PEAT) (available from GreatCell Solar Limited).

### Example 3

A solar cell was produced by the same method as in Example 1 except for the following:
(i) Hexylammonium bromide (HABr) (available from Sigma-Aldrich Co. LLC) was used in the material solution of the coating layer 4 instead of phenethylammonium iodide (PEAT) (available from GreatCell Solar Limited).

### Example 4

A solar cell was produced by the same method as in Example 1 except for the following:
(i) Octylammonium bromide (OABr) (available from Sigma-Aldrich Co. LLC) was used in the material solution of the coating layer 4 instead of phenethylammonium iodide (PEAT) (available from GreatCell Solar Limited).

### Comparative Example 1

A solar cell was produced by the same method as in Example 1 except for the following:
(i) No coating layer 4 was formed.

### Comparative Example 2

A solar cell was produced by the same method as in Example 1 except for the following:
(i) Butylammonium bromide (BABr) (available from Sigma-Aldrich Co. LLC) was used in the material solution of the coating layer 4 instead of phenethylammonium iodide (PEAT) (available from GreatCell Solar Limited).

### Measurement of Solar Cell Characteristic (Voltage)

The open voltage of the solar cells of Examples 1 to 4, Comparative Example 1, and Comparative Example 2 was evaluated by a solar simulator (ALS440B available from BAS Inc.). The evaluation was carried out by using an artificial sunlight with an illumination of 100 mW/cm². The open voltage in Table 1 is an average value of 4 samples of the solar cells of Examples and Comparative Examples. The standard deviation is a measure of variation in open voltage of 4 samples.

TABLE 1

| | | | | Standard |
|---|---|---|---|---|
| | Coating Layer 4 | | | Deviation |
| | | Number of | Open | of Open |
| | Contained | Carbon Atoms | Voltage | Voltage |
| | Compound | in Compound | (unit: mV) | (unit: mV) |
| Example 1 | PEAI | 8 | 1094 | 10.64 |
| Example 2 | PEABr | 8 | 1051 | 9.71 |
| Example 3 | HABr | 6 | 1063 | 19.76 |
| Example 4 | OABr | 8 | 927 | 35.99 |
| Comparative | none | — | 832 | 249.5 |
| Example 1 | | | | |
| Comparative | BABr | 4 | 706 | 339.98 |
| Example 2 | | | | |

### Discussion of Experimental Results

As the solar cells of Examples 1 to 4 including the coating layer 4 are compared with the solar cell of Comparative Example 1 including no coating layer 4, the solar cells of Examples 1 to 4 including the coating layer 4 had a higher open voltage and less variation in open voltage than the solar cell of Comparative Example 1. The materials (i.e., PEAI, PEABr, HABr, and OABr) used in Examples 1 to 4 as materials of the coating layer 4 all similarly showed a higher open voltage and less variation in open voltage. These materials have both an ammonium group having high affinity for the perovskite material used in the photoelectric conversion layer and a long hydrocarbon group having high affinity for hole transport material Spiro-OMeTAD. The material (i.e., BABr) of Comparative Example 2 having a short carbon chain did not function as the coating layer 4. Therefore, the solar cell of Comparative Example 2 had a lower open voltage and more variation in open voltage. From these results, the number of carbon atoms in the compound used in the coating layer 4 needs to be greater than or equal to 6.

The solar cell according to the present disclosure is useful for, for example, a building-integrated solar cell.

What is claimed is:

1. A solar cell comprising:
a substrate;
a first electrode;
a carrier transport layer;
a first photoelectric conversion layer; and
a coating layer,
wherein the first photoelectric conversion layer is disposed between the first electrode and the substrate,
the substrate has a first main surface and a second main surface, and the second main surface of the substrate has an uneven structure,
the first photoelectric conversion layer has a first main surface and a second main surface, and the first main surface and the second main surface of the first photoelectric conversion layer each have an uneven structure,
the coating layer has a first main surface and a second main surface, and the first main surface and the second main surface of the coating layer each have an uneven structure,
the second main surface of the substrate faces the first main surface of the first photoelectric conversion layer,
the second main surface of the first photoelectric conversion layer faces the first main surface of the coating layer,
the second main surface of the coating layer is in contact with the carrier transport layer,
the first photoelectric conversion layer contains a perovskite compound, and
the coating layer contains a compound having 6 or more carbon atoms and containing an ammonium cation.

2. The solar cell according to claim 1, wherein the carrier transport layer is a hole transport layer.

3. The solar cell according to claim 1, wherein the carrier transport layer is an electron transport layer.

4. The solar cell according to claim 1,
wherein the carrier transport layer has a first main surface and a second main surface,
the first main surface and the second main surface of the carrier transport layer each have an uneven structure,
the first main surface of the carrier transport layer faces the second main surface of the coating layer, and
the second main surface of the carrier transport layer faces the first electrode.

5. The solar cell according to claim 1, wherein the carrier transport layer on a recess of the second main surface of the first photoelectric conversion layer has a larger thickness than the carrier transport layer on a protrusion of the second main surface of the first photoelectric conversion layer.

6. The solar cell according to claim 1, wherein the compound contains a compound represented by chemical formula R—X, where R is phenyl ethyl ammonium, hexa-ammonium, or octa-ammonium, and X is a halogen.

7. The solar cell according to claim 1, further comprising a second electrode and a second photoelectric conversion layer,
wherein the second photoelectric conversion layer is disposed between the first main surface of the substrate and the second electrode.

8. The solar cell according to claim 7, wherein the second photoelectric conversion layer contains silicon.

9. The solar cell according to claim 7,
wherein the second photoelectric conversion layer has a first main surface and a second main surface,
the second main surface of the second photoelectric conversion layer has an uneven structure, and
the second main surface of the second photoelectric conversion layer faces the first main surface of the substrate.

10. The solar cell according to claim 1,
wherein the carrier transport layer is a hole transport layer, and
the hole transport layer contains 2,2′,7,7′-tetrakis-(N,N-di-p-methoxyphenylamine)9,9′-spirobifluorene.

11. The solar cell according to claim 10, further comprising an electron transport layer between the substrate and the first photoelectric conversion layer,
wherein the electron transport layer contains TiO₂.
